(19) United States
(12) Patent Application Publication
(10) Pub. No.: US 2024/0155849 A1
(43) Pub. Date: May 9, 2024

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Moorym CHOI, Suwon-si (KR); Sunil SHIM, Suwon-si (KR); Jimin LEE, Suwon-si (KR); Yunsun JANG, Suwon-si (KR)

(21) Appl. No.: 18/372,785

(22) Filed: Sep. 26, 2023

(30) Foreign Application Priority Data
Nov. 7, 2022 (KR) 10-2022-0147093

(51) Int. Cl. H10B 80/00; H01L 23/00; H01L 25/00; H01L 25/065; H01L 25/18; H10B 41/27; H10B 43/27

(52) U.S. Cl. CPC H10B 80/00; H01L 24/08; H01L 24/80; H01L 25/0657; H01L 25/18; H01L 25/50; H10B 41/27; H10B 43/27; H01L 2224/08145; H01L 2224/80895; H01L 2224/80896; H01L 2924/1431; H01L 2924/14511

(57) ABSTRACT

A semiconductor device includes a first semiconductor structure including circuit devices on a first substrate, a lower interconnection structure connected to the circuit devices, and a lower bonding structure connected to the lower interconnection structure; and a second semiconductor structure including a second substrate on the first semiconductor structure, a stopper layer in contact with a lower surface of the second substrate, gate electrodes stacked and spaced apart from each other in a vertical direction, channel structures penetrating through the gate electrodes, and each including a channel layer, an upper interconnection structure below the gate electrodes, a peripheral contact plug spaced apart from the second substrate, and an upper bonding structure bonded to the lower bonding structure, wherein the channel structures penetrate at least a portion of the stopper layer, and wherein the peripheral contact plug penetrates at least a portion of the stopper layer.

### CROSS-REFERENCE TO RELATED APPLICATION

This application claims benefit of priority to Korean Patent Application No. 10-2022-0147093 filed on Nov. 7, 2022 in the Korean Intellectual Property Office, the disclosure of which is incorporated herein by reference in its entirety.

### BACKGROUND

### 1. Field

Example embodiments of the present disclosure relate to a semiconductor device and a data storage system including the same.

### 2. Description of the Related Art

A semiconductor device able to store high-capacity data in a data storage system requiring data storage has been desired. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been proposed.

### SUMMARY

An example embodiment of the present disclosure is to provide a semiconductor device easily manufactured and having improved electrical properties and reliability.

According to an example embodiment of the present disclosure, a semiconductor device includes a first semiconductor structure including a first substrate, circuit devices on the first substrate, a lower interconnection structure electrically connected to the circuit devices, and a lower bonding structure connected to the lower interconnection structure; and a second semiconductor structure including a second substrate on the first semiconductor structure, gate electrodes stacked and spaced apart from each other in a vertical direction perpendicular to a lower surface of the second substrate, channel structures penetrating through the gate electrodes, extending in the vertical direction, and each including a channel layer, an upper interconnection structure below the gate electrodes and the channel structures, and an upper bonding structure connected to the upper interconnection structure and bonded to the lower bonding structure, wherein the second semiconductor structure further includes a first stopper layer between a lower surface of the second substrate and an uppermost gate electrode most adjacent to the second substrate among the gate electrodes, and a second stopper layer on an external side region of the second substrate, and wherein a thickness of the first stopper layer is thinner than a thickness of the second stopper layer.

According to an example embodiment of the present disclosure, a data storage system includes a semiconductor storage device including a first semiconductor structure including a first substrate and circuit devices on the first substrate; a second semiconductor structure including gate electrodes stacked and spaced apart from each other below the second substrate, and channel structures penetrating through the gate electrodes; and an input/output pad electrically connected to the circuit devices; and a controller electrically connected to the semiconductor storage device through the input/output pad and controlling the semiconductor storage device, wherein the first semiconductor structure further includes a lower interconnection structure electrically connected to the circuit devices; and a lower bonding structure connected to the lower interconnection structure, wherein the second semiconductor structure further includes an upper bonding structure bonded to the lower bonding structure; an upper interconnection structure connected to the upper bonding structure; a first stopper layer between a lower surface of the second substrate and an uppermost gate electrode most adjacent to the second substrate among the gate electrodes; and a second stopper layer in an external side region of the second substrate, and wherein a thickness of the first stopper layer is less than a thickness of the second stopper layer and an uppermost end of the channel structures is on a level higher than a level of an upper surface of the first stopper layer.

### BRIEF DESCRIPTION OF DRAWINGS

Features will become apparent to those of skill in the art by describing in detail exemplary embodiments with reference to the attached drawings in which:

FIG. 1 is an exploded perspective diagram illustrating a semiconductor device according to an example embodiment of the present disclosure;

FIG. 2A is a cross-sectional diagram illustrating a semiconductor device according to an example embodiment of the present disclosure;

FIG. 2B is an enlarged cross-sectional diagram illustrating a portion of a semiconductor device according to an example embodiment of the present disclosure;

FIG. 3A is a cross-sectional diagram illustrating a semiconductor device according to an example embodiment of the present disclosure;

FIG. 3B is an enlarged cross-sectional diagram illustrating a portion of a semiconductor device according to an example embodiment of the present disclosure;

FIGS. 4 to 12 are cross-sectional diagrams illustrating a method of manufacturing a semiconductor device according to an example embodiment of the present disclosure;

FIG. 13 is a diagram illustrating a data storage system including a semiconductor device according to an example embodiment of the present disclosure;

FIG. 14 is a perspective diagram illustrating a data storage system including a semiconductor device according to an example embodiment of the present disclosure; and

FIG. 15 is a cross-sectional diagram illustrating a semiconductor package according to an example embodiment of the present disclosure.

### DETAILED DESCRIPTION

Hereinafter, embodiments of the present disclosure will be described as follows with reference to the accompanying drawings.

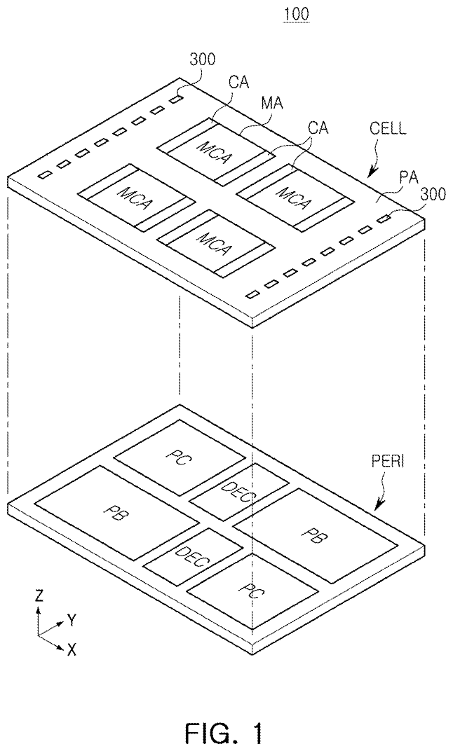

FIG. 1 is an exploded perspective diagram illustrating a semiconductor device according to an example embodiment.

Referring to FIG. 1, a semiconductor device 100 according to example embodiments may include a peripheral circuit region PERI and a memory cell region CELL stacked in a vertical direction Z. The peripheral circuit region PERI and the memory cell region CELL may be bonded and coupled to each other. The memory cell region CELL may include a memory region MA including a memory cell array region MCA and a connection region CA and an external side region PA disposed on an external side of the memory region MA. A first conductive pad 300, which may be an input/output pad, may be disposed on the external side region PA. A plurality of memory regions MA including the memory cell array regions MCA and the connection region CA may be disposed.

The peripheral circuit region PERI may include a row decoder DEC, a page buffer PB and other peripheral circuits PC. In the peripheral circuit region PERI, the row decoder DEC may decode an input address and may generate and transfer driving signals of word lines. The page buffer PB may be connected to the memory cell array region MCA through bit lines and may read information stored in the memory cells. The other peripheral circuit PC may be a region including a control logic and a voltage generator, and may include, for example, a latch circuit, a cache circuit, and/or a sense amplifier. The peripheral circuit region PERI may further include a pad region. In this case, the pad region may include an electrostatic discharge ESD device or a data input/output circuit. The ESD device or data input/output circuit of the pad region may be electrically connected to the first conductive pad 300 of the external side region PA. Various circuit regions DEC, PB, and PC in the peripheral circuit region PERI may be disposed in various forms.

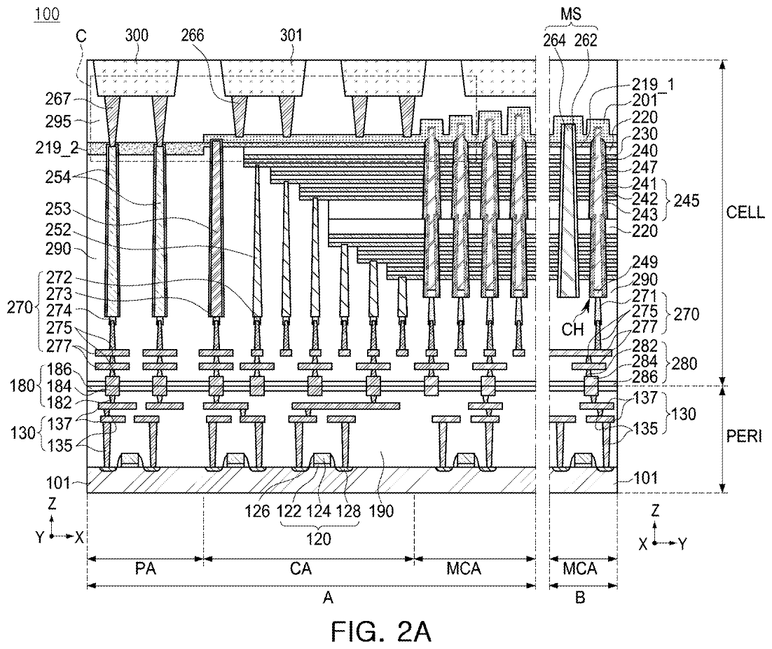

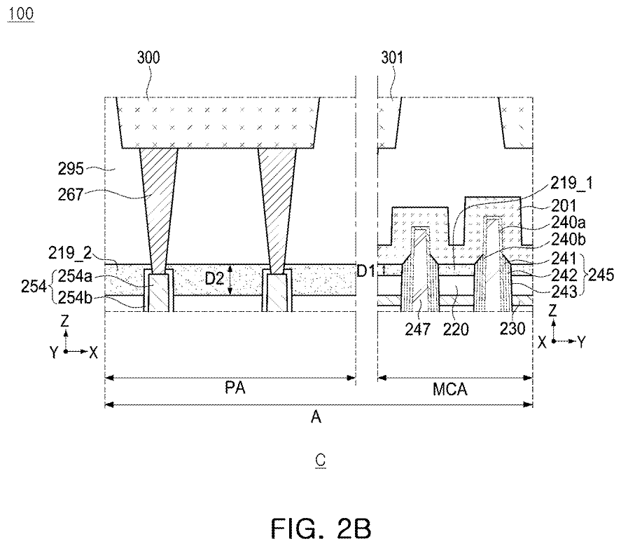

Hereinafter, an example of the semiconductor device 100 will be described with reference to FIGS. 2A and 2B. In FIG. 2A, region “A” is a cross-section of a portion of a memory cell array region MCA, a connection region CA, and a portion of an external side region PA illustrated in FIG. 1 taken in the X-direction, and region “B” includes a cross-section of a portion of the memory cell array region MCA illustrated in FIG. 1 taken in the Y-direction.

FIG. 2A is a cross-sectional diagram illustrating a semiconductor device according to an example embodiment. FIG. 2B is an enlarged cross-sectional diagram illustrating a portion of a semiconductor device in the example embodiment, illustrating region “C” in FIG. 2A.

Referring to FIGS. 2A and 2B, the semiconductor device 100 may include a peripheral circuit region PERI and a memory cell region CELL. The memory cell region CELL may be disposed on a peripheral circuit region PERI. The peripheral circuit region PERI and the memory cell region CELL may be bonded to each other through bonding structures 180 and 280. The peripheral circuit region PERI may be referred to as a first semiconductor structure, and the memory cell region CELL may be referred to as a second semiconductor structure.

The peripheral circuit region PERI may include a first substrate 101, circuit devices 120 on the first substrate 101, a lower interconnection structure 130, a lower bonding structure 180, and a lower capping layer 190.

The first substrate 101 may include a semiconductor material, for example, a group IV semiconductor, a group III-V compound semiconductor, or a group II-VI compound semiconductor. The first substrate 101 may be provided as a bulk wafer or an epitaxial layer. An active region may be defined on the first substrate 101 by device isolation layers. Source/drain regions 128 including impurities may be disposed in a portion of the active region.

The circuit devices 120 may include transistors. Each circuit device 120 may include a circuit gate dielectric layer 122, a circuit gate electrode 124, and a source/drain region 128. The source/drain regions 128 including impurities may be disposed in the first substrate 101 on both sides of the circuit gate electrode 124. The spacer layers 126 may be disposed on both sides of the circuit gate electrode 124. The circuit gate dielectric layer 122 may include silicon oxide, silicon nitride, or a high-k material. The circuit gate electrode 124 may include at least one of titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), and ruthenium (Ru). The circuit gate electrode 124 may include a semiconductor layer, for example a doped polycrystalline silicon layer. In the example embodiment, the circuit gate electrode 124 may include two or more multiple layers.

The lower interconnection structure 130 may be electrically connected to the circuit gate electrodes 124 and the source/drain regions 128 of the circuit devices 120. The lower interconnection structure 130 may include lower contact plugs 135 having a cylindrical or truncated cone shape and lower interconnection lines 137 of which at least one region has a line shape. A portion of the lower contact plugs 135 may be connected to the source/drain regions 128, and although not illustrated, other portions of the lower contact plugs 135 may be connected to the gate electrodes 124. The lower contact plugs 135 may electrically connect lower interconnection lines 137 disposed on different levels from the upper surface of the first substrate 101 to each other. The lower interconnection structure 130 may include a conductive material, for example, tungsten (W), copper (Cu), and aluminum (Al), and each component may further a diffusion barrier including at least one of titanium (Ti), titanium nitride (TiN), tantalum (Ta), tantalum nitride (TaN), and tungsten nitride (WN). In example embodiments, the number of layers of the lower contact plugs 135 and the lower interconnection lines 137 included in the lower interconnection structure 130 and arrangement thereof may vary.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and the lower bonding pad 184 may include a conductive material, for example, tungsten (W), copper (Cu), and aluminum (Al), and each component may further include a diffusion barrier. The lower bonding insulating layer 186 may also function as a diffusion barrier of the lower bonding pad 184 and may include at least one of SiCN, SiO, SiN, SiOC, SiON, and SiOCN. The lower bonding insulating layer 186 may have a thickness less than that of the lower bonding pad 184, as a non-limiting example. The lower bonding structure 180 may be bonded or connected by direct contact with the upper bonding structure 280 by hybrid bonding. For example, the lower bonding pad 184 may be in contact with, and bonded to, the upper bonding pad 284 by copper-to-copper bonding The lower bonding insulating layer 186 may be in contact with, and bonded to, the upper bonding insulating layer 286 by dielectric-to-dielectric bonding. The lower bonding structure 180 may provide an electrical connection path between the peripheral circuit region PERI and the memory cell region CELL together with the upper bonding structure 280.

The lower capping layer 190 may be located on the first substrate 101 and may cover the circuit devices 120 and the lower interconnection structure 130. The lower capping layer 190 may include a plurality of insulating layers. The lower capping layer 190 may include an insulating material such as silicon oxide, silicon nitride, silicon oxynitride, or silicon oxycarbide.

The memory cell region CELL may include: a second substrate 201, stopper layers 219_1 and 219_2 located below the second substrate 201, gate electrodes 230 stacked below the second substrate 201, isolation region MS extending by penetrating through a stack structure of the gate electrodes 230, channel structures CH disposed to penetrate through the stack structure, contact plugs 252, 253, and 254 for electrical connection with the peripheral circuit region PERI, an upper interconnection structure 270 located below the stack structure, and an upper bonding structure 280 connected to the upper interconnection structure 270.

The memory cell region CELL may further include interlayer insulating layers 220 alternately stacked with the gate electrodes 230 disposed below the second substrate 201, a peripheral contact pad 265 and a peripheral contact via 267 on the peripheral contact plug 254 among the contact plugs 252, 253, and 254, an upper capping layer 290 covering the stack structure, an upper insulating layer 295 in contact with an end of the external side of the second substrate 201 and disposed on the second substrate 201, and a first conductive pad 300 on a peripheral contact via 267.

In the memory cell region CELL, a memory cell array region MCA, a connection region CA, and an external side region PA may be defined based on, for example, the second substrate 201 and surrounding components thereof.

In the memory cell array region MCA, as illustrated in FIG. 2A, gate electrodes 230 may be stacked and spaced apart from each other in a vertical direction, for example, the Z-direction, and the channel structures CH may be disposed. As illustrated in FIG. 2A, the connection region CA may be a region in which the gate electrodes 230 may extend to different lengths and may provide contact pads for electrically connecting memory cells to the peripheral circuit region PERI. Also, the connection region CA may be a region in which the source contact plug 253 may be disposed. The memory cell array region MCA and the connection region CA may be a region including the second substrate 201 and both lower and upper regions of the second substrate 201.

As illustrated in FIG. 2A, the external side region PA may refer to a region from an external side end of the second substrate 201 to an edge of the semiconductor device 100, and the first conductive pad 300 and the peripheral contact plug 254 may be disposed in the region. The external side region PA may be a region other than a region in which the memory cell array region MCA and the connection region CA are disposed in the memory cell region CELL. The term “external side region PA” may refer to a region in which the second stopper layer 219_2 disposed on the external side of the second substrate 201 is disposed, or a region that includes both the region below and above the second stopper layer 219_2, including the second stopper layer 219_2.

The second substrate 201 may include a semiconductor material, for example, a group IV semiconductor, a group III-V compound semiconductor, or a group II-VI compound semiconductor. For example, the group IV semiconductor may include silicon (Si), germanium (Ge), or silicon-germanium (SiGe). The second substrate 201 may function as a common source line of the semiconductor device 100. For example, the second substrate 201 may include a doped polysilicon layer having N-type conductivity. The channel layer 240 may contact the second substrate 201. In the example embodiment, the second substrate 201 may conformally cover the channel structures CH and the source contact plug 253, as a non-limiting example.

The stopper layers 219_1 and 219_2 may contact the lower surface of the second substrate 201 and may extend in a first direction x parallel to the lower surface of the second substrate 201. The stopper layers 219_1 and 219_2 may further include a first stopper layer 219_1 disposed between the lower surface of the second substrate 201 and the uppermost gate electrode 230 closest to the second substrate 201 among the gate electrodes 230, and a second stopper layer 219_2 disposed on the external side region PA of the second substrate 201. An upper surface of the first stopper layer 219_1 and an upper surface of the second stopper layer 219_2 may be coplanar with each other. The first stopper layer 219_1 and the second stopper layer 219_2 may include an insulating material. The first stopper layer 219_1 and the second stopper layer 219_2 may include, for example, oxide, nitride, oxynitride, and/or undoped poly silicon. In an example embodiment, the first stopper layer 219_1 and the second stopper layer 219_2 may include aluminum oxide (Al₂O₃).

As illustrated in FIG. 2B, the first stopper layer 219_1 may contact the channel structure CH, and the second stopper layer 219_2 may contact the peripheral contact plug 254. The thickness D1 of the first stopper layer 219_1 may be less than the thickness D2 of the second stopper layer 219_2. The thickness D2 of the second stopper layer 219_2 may be greater than or equal to about 50 nm and less than or equal to about 100 nm. For example, the thickness D2 of the second stopper layer 219_2 may be greater than or equal to about 50 nm and less than or equal to about 70 nm. The thickness D1 of the first stopper layer 219_1 may be greater than or equal to about 5 nm and less than or equal to about 50 nm. If the thickness of the first stopper layer 219_1 were to be greater than the above range, the uppermost end of the channel structure CH may be present within the first stopper layer 219_1 Accordingly, the channel layer 240 may be spaced apart from the second substrate 201 and may not be electrically connected to the second substrate 201.

The gate electrodes 230 may be vertically stacked and spaced apart from each other below the second substrate 201 and may form a stack structure. The gate electrodes 230 may be disposed between the second substrate 201 and the upper interconnection structure 270. The gate electrodes 230 may include electrodes forming a ground select transistor, memory cells, and a string select transistor in order from the second substrate 201. The number of gate electrodes 230 included in the memory cells may be determined depending on the storage capacity of the semiconductor device 100. In example embodiments, the number of gate electrodes 230 included in the string select transistor and the ground select transistor may be one or two or more, and may have the same structure as or a different structure from that of the gate electrodes 230 of the memory cells. Also, the gate electrodes 230 may further include gate electrodes 230 that are disposed below the gate electrode 230 that is included in the string selection transistor and above the gate electrode 230 that is included in the ground selection transistor and included in an erase transistor used for an erase operation using a gate induced drain leakage (GIDL) phenomenon.

The gate electrodes 230 may be stacked and spaced apart from each other in a vertical direction in the memory cell array region MCA. The gate electrodes 230 may extend in different lengths from the memory cell array region MCA to the connection region CA and may form a step structure in a staircase shape. As illustrated in FIG. 2A, the gate electrodes 230 may have a step structure in the X-direction and may be disposed to have a step structure in the Y-direction. Due to the step structure, the gate electrodes 230 may form a staircase shape in which the upper gate electrode 230 extends longer than the lower gate electrode 230 The gate electrodes 230 may provide ends exposed toward the first substrate 101 from the interlayer insulating layers 220. In example embodiments, the gate electrodes 230 may have an increased thickness on the ends. Although not illustrated, a portion of electrodes included in the string select transistor among the gate electrodes 230 may be isolated by an isolation insulation layer extending in the X-direction.

The gate electrodes 230 may form a lower gate stack group and an upper gate stack group on the lower gate stack group. The interlayer insulating layer 220 disposed between the lower gate stack group and the upper gate stack group may have a relatively thick thickness, as a non-limiting example. In FIG. 2A, two stack groups of gate electrodes 230 are shown that are disposed vertically, as a non-limiting example. The gate electrodes 230 may form a stack group or a plurality of stack groups.

The gate electrodes 230 may include a metal material, such as tungsten (W). In example embodiments, the gate electrodes 230 may include polycrystalline silicon or a metal silicide material. In example embodiments, the gate electrodes 230 may further include a diffusion barrier. For example, the diffusion barrier may include tungsten nitride (WN), tantalum nitride (TaN), titanium nitride (TiN) or combinations thereof.

The interlayer insulating layers 220 may be disposed between the gate electrodes 230. Similarly to the gate electrodes 230, the interlayer insulating layers 220 may be spaced apart from each other in a direction perpendicular to the lower surface of the second substrate 201 and may be disposed to extend in the X-direction. The interlayer insulating layers 220 may include an insulating material such as silicon oxide or silicon nitride.

The isolation region MS may be disposed to extend in the Z-direction through the gate electrodes 230 in the memory cell array region MCA and the connection region CA. The isolation region MS may penetrate through the entire gate electrodes 230 stacked below the second substrate 201 and may be connected to the second substrate 201. The isolation region MS may have a shape in which a width decreases toward the second substrate 201 due to a high aspect ratio. The isolation region MS may extend in the X-direction and may isolate the gate electrodes 230 from each other in the Y-direction. The isolation regions MS may include a conductive layer 262 and an isolation insulation layer 264. The isolation insulation layer 264 may cover side surfaces of the conductive layer 262. The conductive layer 262 may be connected to the second substrate 201. The isolation insulation layer 264 may include an insulating material such as silicon oxide or silicon nitride, and the conductive layer 262 may include a conductive material, for example, tungsten (W), copper (Cu), and aluminum (Al).

The channel structures CH may form a memory cell string. The channel structures CH may be spaced apart from each other to form rows and columns in the memory cell array region MCA. The channel structures CH may be disposed to form a lattice pattern on an X-Y plane or may be disposed in a zigzag pattern in one direction. The channel structures CH may penetrate through the gate electrodes 230 and may extend in a vertical direction perpendicular to the lower surface of the second substrate 201, for example, in the Z-direction. The channel structures CH may have a columnar shape, and may have an inclined side surface the width of which may decrease toward the second substrate 201 depending on an aspect ratio.

Each of the channel structures CH may have a form in which lower and upper channel structures that penetrate through the lower gate stack group and the upper gate stack group of the gate electrodes 230 may be connected to each other, and may have a bent portion due to a difference or change in width in the connection region.

A channel layer 240 may be disposed in the channel structures CH. The channel layer 240 may be connected between the lower channel structure and the upper channel structure. As shown in FIG. 2B, the channel layer 240 may include protrusions 240a and non-protrusions 240b of the channel layer 240. In some non-limiting examples, the protruding lengths of the protrusions 240a from the channel structures CH may not be the same. The channel layer 240 may be formed in an annular shape surrounding the internal channel filling the insulating layer 247, or may have a column shape such as a cylindrical shape or a prism shape without the channel filling insulating layer 247 according to example embodiments. The protrusion 240a of the channel layer 240 may be connected to the second substrate 201 on the channel layer 240. The channel layer 240 may include a semiconductor material such as polycrystalline silicon or single crystal silicon. The semiconductor material may be an undoped material or a material including p-type or n-type impurities. In the example embodiment, the channel structure CH may penetrate through at least a portion of the first stopper layer 219_1. The uppermost end of the channel structure CH may be disposed on a level higher than a level of the upper surface of the first stopper layer 219_1 and the second stopper layer 219_2. For example, when the uppermost end of the channel layer 240 is disposed on a level higher than a level of the upper surfaces of the first stopper layer 219_1 and the second stopper layer 219_2, an uppermost end of the channel layer 240 may contact the second substrate 201.

Channel pads 249 may be disposed below the channel layer 240 in the channel structures CH. The channel pads 249 may cover a lower surface of the channel filling insulating layer 247 and may be electrically connected to the channel layer 240. The channel pads 249 may include, for example, doped polycrystalline silicon.

The channel dielectric layer 245 may be disposed between the gate electrodes 230 and the channel layer 240. The channel dielectric layer 245 may include a tunneling layer 241, a charge storage layer 242, and a blocking layer 243 stacked in order from the channel layer 240. The tunneling layer 241 may tunnel electric charges into the charge storage layer 242. The tunneling layer 241 may include, for example, silicon oxide (SiO₂), silicon nitride (Si₃N₄), silicon oxynitride (SiON), or a combination thereof. The charge storage layer 242 may be a charge trap layer or a floating gate conductive layer. The blocking layer 243 may include silicon oxide (SiO₂), silicon nitride (Si₃N₄), silicon oxynitride (SiON), a high-k dielectric material, or a combination thereof. In example embodiments, at least a portion of the channel dielectric layer 245 may extend in a horizontal direction along the gate electrodes 230. In the example embodiment, when the channel structures CH penetrate through the first stopper layer 219_1, the channel dielectric layer 245 may contact the first stopper layer 219_1.

Each of the contact plugs 252, 253, and 254 may have a cylindrical shape or a truncated cone shape, and may have a width decreasing upwardly depending on an aspect ratio. The contact plugs 252, 253, and 254 may penetrate through a portion of the upper capping layer 290. The contact plugs 252, 253, and 254 may include a gate contact plug 252, a source contact plug 253, and a peripheral contact plug 254. Each of the gate contact plug 252, the source contact plug 253, and the peripheral contact plug 254 may be spaced apart from each other and a plurality of the gate contact plug 252, a plurality of the source contact plug 253, and a plurality of the peripheral contact plug 254 may be disposed. Each of the contact plugs 252, 253, and 254 may include a conductive layer and a barrier layer surrounding side surfaces and one end of the conductive layer. For example, as illustrated in FIG. 2B, each of the contact plugs 253 and 254 may include conductive layers 253a and 254a and barrier layers 253b and 254b, and the barrier layers 253b and 254b may surround upper surfaces and side surfaces of the conductive layers 253a and 254a. The conductive layers 253a and 254a may include a conductive material, for example, a metal material such as tungsten (W), copper (Cu), or aluminum (Al), and the barrier layers 253b, 254b may include, for example, at least one of titanium (Ti), titanium nitride (TiN), tantalum (Ta), tantalum nitride (TaN), tungsten nitride (WN), and tungsten carbon nitride (WCN).

The gate contact plugs 252 may be disposed in the connection region CA and may extend in a vertical direction, for example, in a Z-direction. The gate contact plugs 252 may be connected to contact pads or end portions of the gate electrodes 230 having a staircase shape. The gate contact plugs 252 may be connected to the upper interconnection structure 270 in a lower portion.

The source contact plug 253 may extend in a vertical direction, for example, in the Z-direction. In the example embodiment, the source contact plug 253 may penetrate through at least a portion of the first stopper layer 219_1. For example, the source contact plug 253 may be disposed to be partially recessed into the second substrate 201 and may be connected to the second substrate 201. With respect to the upper surface of the first substrate 101, the lower surface of the source contact plug 253 may be disposed on a lower level than a level of the lowermost gate electrode 230 among the gate electrodes 230. For example, the lower surface may extend from a level lower than the lowermost gate electrode 230 most adjacent to the first semiconductor structure among the gate electrodes 230 to at least the internal region of the second substrate 201. The lower surface of the source contact plug 253 may be connected to the upper interconnection structure 270. The width of an upper surface of the source contact plug 253 may be less than a width of a lower surface. The source contact plug 253 may be formed in the same process as the process of forming the peripheral contact plug 254, and may have a shape the same as or similar to the peripheral contact plug 254.

The peripheral contact plug 254 may be spaced apart from the second substrate 201 and the source contact plug 253 on the external side of the second substrate 201 and may extend in a vertical direction, for example, in the Z-direction. The peripheral contact plug 254 may penetrate through at least a portion of the second stopper layer 219_2. For example, the peripheral contact plug 254 may contact the second stopper layer 219_2 in the external side region PA of the second substrate 201. In the example embodiment, the uppermost end of the peripheral contact plug 254 may be disposed in the second stopper layer 219_2. The peripheral contact plug 254 may be connected to the upper interconnection structure 270. The peripheral contact plug 254 may penetrate through a portion of the upper capping layer 290 and the second stopper layer 219_2 and may land on the second stopper layer 219_2. Accordingly, process difficulty with regard to the peripheral contact via 267 connected to the peripheral contact plug 254 may be addressed, and process difficulty with regard to the via patterns 266 connected to the second substrate 201 may be addressed. Accordingly, process difficulty of manufacturing the semiconductor device 100 and a risk of defects of the semiconductor device 100 may be addressed.

In the peripheral contact via 267 and the via patterns 266, the width of the lower region may be less than the width of the upper region. The peripheral contact via 267 may be formed on the second stopper layer 219_2 of the external side region PA. The via patterns 266 may be formed on the second substrate 201 of the connection region CA and/or the memory cell array region MCA. The via patterns 266 may be disposed between the second conductive pad 301 and the second substrate 201. In the example embodiment, a level of a lower surface of the via patterns 266 may be lower than a level of an upper surface of the second substrate 201. A level of a lower portion of the peripheral contact via 267 may be lower than a level of a lower surface of the via patterns 266. In the example embodiment, the peripheral contact via 267 may penetrate through at least a portion of the second stopper layer 219_2 and may be in contact with the peripheral contact plug 254. In the example embodiment, the peripheral contact via 267 may include aluminum (Al). The peripheral contact via 267 may be connected to the first conductive pad 300. The peripheral contact via 267 may include a plurality of vias connected to the first conductive pad 300. The peripheral contact via 267 and the via patterns 266 may be formed of a metal material, for example, tungsten (W) or aluminum (Al).

The upper interconnection structure 270 may electrically connect the gate electrodes 230, the channel structures CH, the second substrate 201, and the first conductive pad 300 to the circuit devices 120. The upper interconnection structure 270 may include a channel contact plug 271, a gate contact stud 272, a source contact stud 273, a peripheral contact stud 274, an upper contact plug 275, and an upper interconnection line 277. The channel contact plug 271 may be connected to the channel pad 249 of the channel structure CH. The channel contact plug 271 may be electrically connected to the channel layer 240 through the channel pad 249 of the channel structures CH in the memory cell array region MCA. The gate contact stud 272 may be connected to the gate contact plug 252. The source contact stud 273 may be connected to the source contact plug 253. The peripheral contact stud 274 may be connected to the peripheral contact plug 254. The upper contact plugs 275 may be connected to the channel contact plug 271, the gate contact stud 272, the source contact stud 273, and the peripheral contact stud 274, respectively. The upper interconnection line 277 may be connected to the upper contact plug 275. The upper interconnection structure 270 may include a conductive material, for example, tungsten (W), copper (Cu), and aluminum (Al). Each component may include a diffusion barrier including at least one of titanium (Ti), titanium nitride (TiN), tantalum (Ta), tantalum nitride (TaN), and tungsten nitride (WN). In example embodiments, the number of layers of the upper contact plugs 275 and the upper interconnection lines 277 included in the upper bonding structure 280 and arrangement thereof may vary.

The upper bonding structure 280 may be connected to the upper interconnection structure 270. For example, the gate contact stud 272 and the channel contact plug 271 may be electrically connected to the upper bonding structure 280. The upper bonding structure 280 may include an upper bonding via 282, an upper bonding pad 284, and an upper bonding insulating layer 286. The upper bonding via 282 may be connected to the upper interconnection structure 270. The upper bonding pad 284 may be connected to the upper bonding via 282. The upper bonding via 282 and the upper bonding pad 284 may include a conductive material, for example, tungsten (W), copper (Cu), and aluminum (Al), and each component may further include a diffusion barrier. The upper bonding insulating layer 286 may function as a diffusion barrier of the upper bonding pad 284 and may include at least one of SiCN, SiO, SiN, SiOC, SiON, and SiOCN. The upper bonding insulating layer 286 may have a thickness less than that of the upper bonding pad 284, as a non-limiting example.

The upper capping layer 290 may be disposed below the second substrate 201, and may cover the second substrate 201, the substrate insulating layer 219, the first stopper layer 219_1, the second stopper layer 219_2, and the gate electrodes 230. The upper capping layer 290 may include a plurality of insulating layers. The upper capping layer 290 may include an insulating material such as silicon oxide, silicon nitride, silicon oxynitride, or silicon oxycarbide.

An upper insulating layer 295 may be disposed on the second substrate 201. The upper insulating layer 295 may include an upper insulating layer 295 covering a first stopper layer 219_1, a second stopper layer 219_2, a second substrate 201, a peripheral contact via 267, via patterns 266, a first conductive pad 300, and a second conductive pad 301. The upper insulating layer 295 may include an insulating material such as silicon oxide, silicon nitride, silicon oxynitride, or silicon oxycarbide.

The first conductive pad 300 and the second conductive pad 301 may be disposed on the upper insulating layer 295. The first conductive pad 300 may be electrically connected to the peripheral contact plug 254 on the peripheral contact plug 254. The second conductive pad 301 may be electrically connected to the second substrate 201 on the second substrate 201. Accordingly, the semiconductor device 100 having reduced electrical resistance and improved electrical properties may be provided. The second conductive pad 301 may be in contact with the via patterns 266 disposed between the second substrate 201 and the second conductive pad 301. The second conductive pad 301 may be disposed on substantially the same level that of the first conductive pad 300.

The first conductive pad 300 may be an input/output pad of the semiconductor device 100 and may be electrically connected to the controller. The first conductive pad 300 may be disposed on the peripheral contact via 267, and the first conductive pad 300 may be in contact with the peripheral contact via 267. The first conductive pad 300 may be electrically connected to the circuit devices 120 of the peripheral circuit region PERI. The first conductive pad 300 and the second conductive pad 301 may include a conductive material, for example, aluminum (Al).

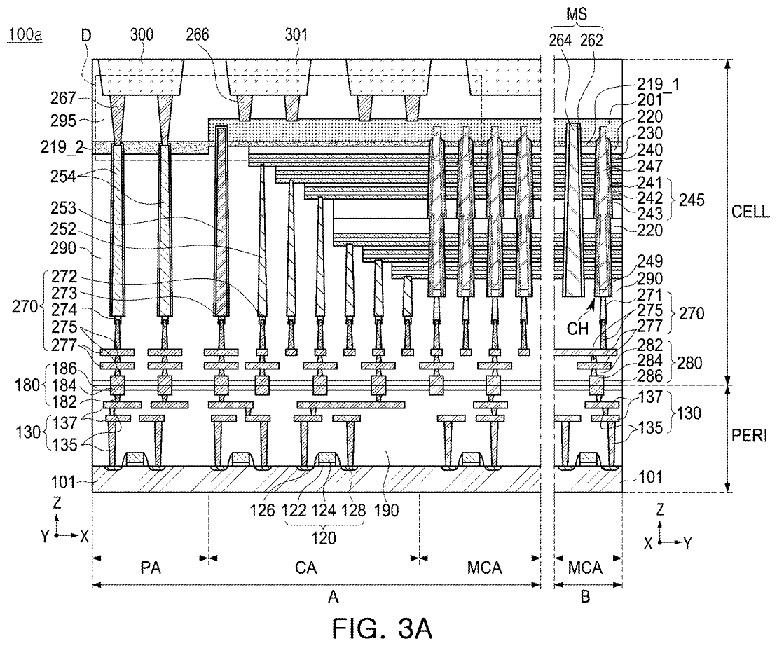

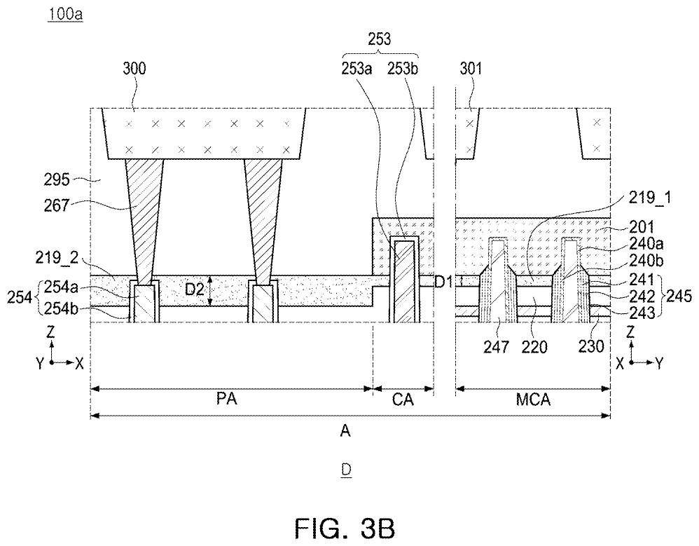

FIG. 3A is a cross-sectional diagram illustrating a semiconductor device according to an example embodiment.

FIG. 3B is an enlarged cross-sectional diagram illustrating a portion of a semiconductor device in the example embodiment, illustrating region “D” in FIG. 3A. The same reference numerals as those in FIG. 2A indicate corresponding components, and overlapping descriptions thereof will not be repeated.

Referring to FIGS. 3A and 3B, the upper surface of the second substrate 201 may not be curved. For example, the upper surface of the second substrate 201 may form a plane parallel to the upper surface of the first substrate 101. The uppermost ends of the channel structures CH may be disposed on the same level, as non-limiting examples. For example, the protruding lengths of the respective protrusions 240a of the channel structures CH may be substantially the same, and the upper surface of the channel layer 240 may have the same level. The configuration in which the upper surface of the second substrate 201 is parallel to the upper surface of the first substrate 101 may be independent of the configuration in which the upper surface of the channel layer 240 has the same level. For example, when the upper surface of the second substrate 201 is configured to be curved, the upper surface of the channel layer 240 may have the same level. Also, when the upper surface of the second substrate 201 is not configured to be curved and is parallel to the upper surface of the first substrate 101, the upper surface of the channel layer 240 may not have the same level. The upper surface of the source contact plug 253 may be disposed on substantially the same level as a level of the upper surface of the channel layer 240 as non-limiting examples.

In the example embodiment, the source contact plug 253 may penetrate through the first stopper layer 219_1 and may be electrically connected to the second substrate 201, as a non-limiting example. For example, when the side surface of the second stopper layer 219_2 contacts the interlayer insulating layers 220, the source contact plug 253 may penetrate through the second stopper layer 219_2 and may be electrically connected to the second substrate 201.

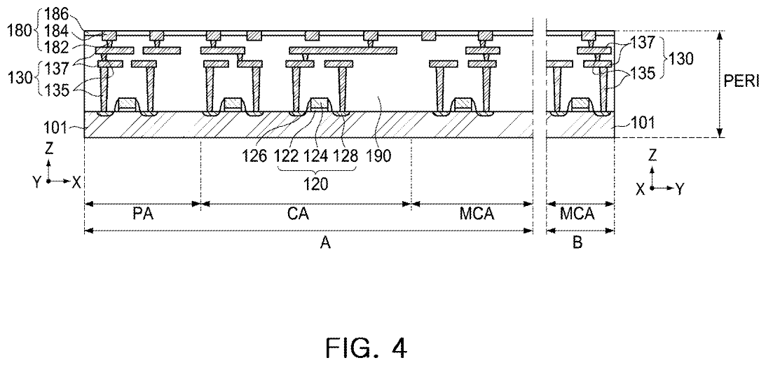

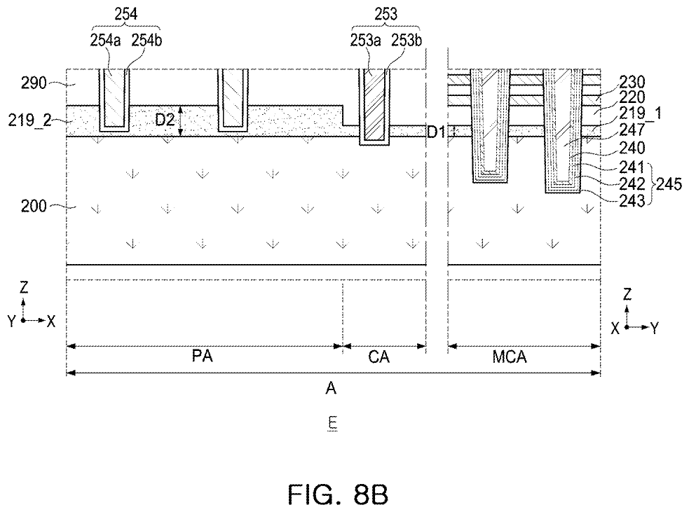

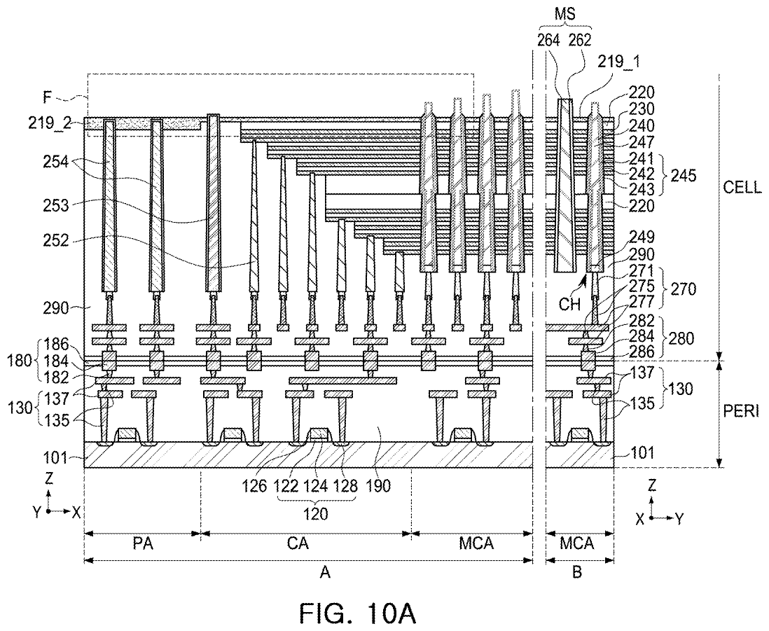

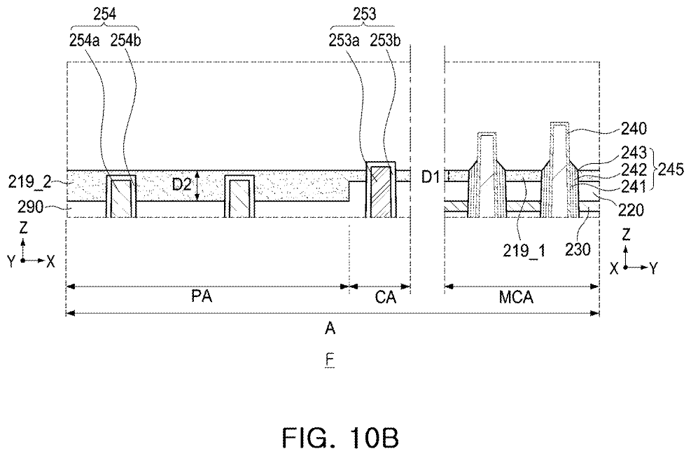

FIGS. 4 to 12 are cross-sectional diagrams illustrating a method of manufacturing a semiconductor device in the example embodiment, illustrating regions corresponding to the region illustrated in FIG. 2A. FIGS. 8B and 10B are enlarged cross-sectional diagrams illustrating a portion of a semiconductor device according to an example embodiment. FIG. 8B illustrates region “E” of FIG. 8A, and FIG. 10B illustrates region “F” OF FIG. 10A.

Referring to FIG. 4, circuit devices 120 included in a peripheral circuit region PERI on a first substrate 101, a lower interconnection structure 130, a lower bonding structure 180, and a lower capping layer 190 may be formed.

First, device isolation layers may be formed in the first substrate 101, and the circuit gate dielectric layer 122 and the circuit gate electrode 124 may be formed in sequence on the first substrate 101. The device isolation layers may be formed by, for example, a shallow trench isolation (STI) process. The circuit gate dielectric layer 122 may be formed on the first substrate 101, and the circuit gate electrode 124 may be formed on the circuit gate dielectric layer 122. Thereafter, spacer layers 126 may be formed on both sidewalls of the circuit gate dielectric layer 122 and the circuit gate electrode 124, and source/drain regions 128 may be formed by injecting impurities into the active region of the first substrate 101 on both sides of the circuit gate electrode 124.

The lower contact plugs 135 of the lower interconnection structure 130 may be formed by partially forming the lower capping layer 190, removing a portion by etching, and filling a conductive material. The lower interconnection lines 137 may be formed by, for example, depositing a conductive material and patterning the material.

In the lower bonding structures 180, the lower bonding vias 182 may be formed by forming a portion of the lower capping layer 190, removing the portion by etching, and filling a conductive material therein. The lower bonding pad 184 may be formed by, for example, depositing a conductive material and patterning the material. The lower bonding structure 180 may be formed by, for example, a deposition process or a plating process. The lower bonding insulating layer 186 may be formed by covering the upper surface and the side surfaces of the lower bonding pad 184, and performing a planarization process the upper surface of the lower bonding pad 184 is exposed.

The lower capping layer 190 may include a plurality of insulating layers. The lower capping layer 190 may become a portion in each process of forming the lower interconnection structure 130 and the lower bonding structure 180. Accordingly, a peripheral circuit region PERI may be formed.

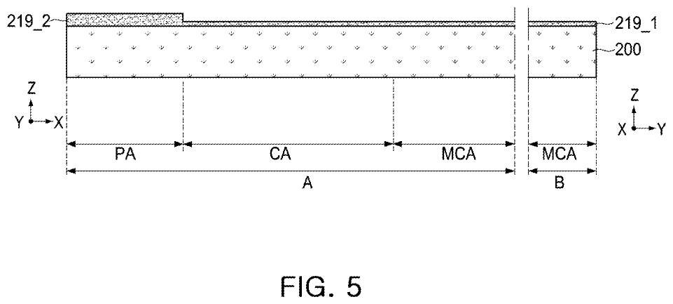

Referring to FIG. 5, a first stopper layer 219_1 and a second stopper layer 219_2 may be formed on the base substrate 200. The base substrate 200 may include a semiconductor material, for example, a group IV semiconductor, a group III-V compound semiconductor, or a group II-VI compound semiconductor. The base substrate 200 may be provided to control the thickness of the second substrate 201 in a process of removing the base substrate 200 described below.

The first stopper layer 219_1 and the second stopper layer 219_2 may have different thicknesses. In the example embodiment, the stopper layers 219_1 and 219_2 may be formed by depositing an insulating material on the base substrate 200. Thereafter, by etching the first stopper layer 219_1 in the connection region CA and the memory cell array region MCA using a mask, the first stopper layer 219_1 having a thickness less than the thickness of the second stopper layer 219_2 may be formed on the second stopper layer 219_2. In the example embodiment, the stopper layers 219_1 and 219_2 may be formed by depositing an insulating material on the base substrate 200. Thereafter, by depositing the same insulating material as that of the first stopper layer 219_1 to a thickness greater than the thickness of the first stopper layer 219_1 in the region on the external side region PA in which the second stopper layer 219_2 is formed using a mask, the second stopper layer 219_2 may be formed on the first stopper layer 219_1, as a non-limiting example. The second stopper layer 219_2 may be formed by a method of depositing an insulating material different from the method of forming the first stopper layer 219_1.

However, methods of forming the first stopper layer 219_1 and the second stopper layer 219_2 of the example embodiments may vary.

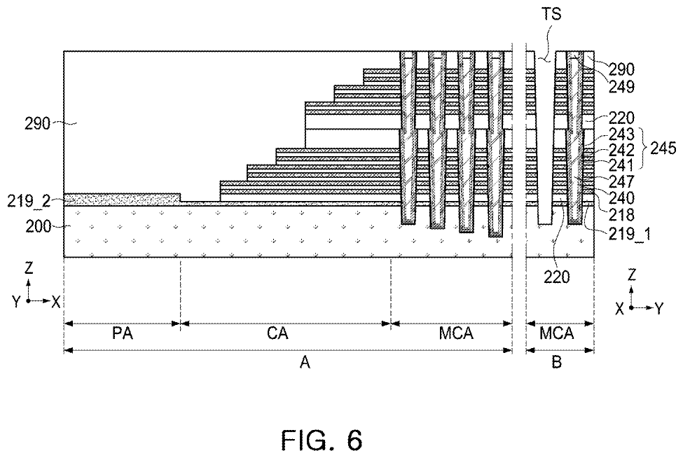

Referring to FIG. 6, a lower stack structure may be formed by alternately stacking sacrificial insulating layers 218 and interlayer insulating layers 220. An upper stack structure may be formed by alternately stacking the sacrificial insulating layers 218 and the interlayer insulating layers 220. Thereafter, channel structures CH penetrating through the stack structure of the sacrificial insulating layers 218 and the interlayer insulating layers 220 may be formed. An isolation opening TS penetrating through the stack structure of the sacrificial insulating layers 218 and the interlayer insulating layers 220 may be formed in a region corresponding to the isolation region MS (see FIG. 2A).

A portion of the sacrificial insulating layers 218 may be replaced with gate electrodes 230 (see FIG. 2A) through a subsequent process. The sacrificial insulating layers 218 may be formed of a material different from that of the interlayer insulating layers 220 The sacrificial insulating layers 218 may be formed of a material etched with etch selectivity for the interlayer insulating layers 220 under specific etching conditions. For example, the interlayer insulating layer 220 may be formed of at least one of silicon oxide and silicon nitride, and the sacrificial insulating layers 218 may be formed of a material different from that of the interlayer insulating layers 220, selected from among silicon, silicon oxide, silicon carbide, and silicon nitride. In example embodiments, the interlayer insulating layers 220 may not have the same thickness. The thicknesses of the interlayer insulating layers 220 and the sacrificial insulating layers 218 and the number of layers thereof may vary from the illustrated example.

A photolithography process and an etching process may be repeatedly performed on the sacrificial insulating layers 218 using a mask layer such that the upper sacrificial insulating layers 218 extend shorter than the lower sacrificial insulating layers 218 in the connection region CA. Accordingly, the sacrificial insulating layers 218 may form a step structure in a staircase shape in predetermined units.

Vertical sacrificial structures may be formed to penetrate through the lower stack structure. The vertical sacrificial structures may be formed by anisotropically etching the lower stack structure of the sacrificial insulating layers 218 and the interlayer insulating layers 220 using a mask layer, and by forming hole-shaped lower channel holes, and filling the holes. When forming the vertical sacrificial structures, the first stopper layer 219_1 may function as an etch stop layer. At least a portion of the vertical sacrificial structures may be formed to be recessed into the base substrate 200 at different depths, as a non-limiting example. The vertical sacrificial structure may include a semiconductor material such as polycrystalline silicon. In the example embodiment, the vertical sacrificial structure may include at least one of silicon oxide, silicon nitride, and silicon oxynitride. After forming the vertical sacrificial structure, an upper stack structure of the sacrificial insulating layers 218 and the interlayer insulating layers 220 may be formed on the lower stack structure and the vertical sacrificial structure.

Thereafter, an upper capping layer 290 covering the stack structure of the sacrificial insulating layers 218 and the interlayer insulating layers 220 may be partially formed.

The channel structures CH may be formed by forming upper holes in the vertical sacrificial structure, removing the vertical sacrificial structure to form hole-shaped channel holes, and filling the channel holes with a plurality of layers. The plurality of layers may include a channel dielectric layer 245, a channel layer 240, a channel filling insulating layer 247, and a channel pad 249. The upper channel holes of the channel holes may be formed by anisotropically etching the upper stack structure of the sacrificial insulating layers 218 and the interlayer insulating layers 220 using a separate mask layer. The lower channel holes of the channel holes may be formed by removing a vertical sacrificial structure exposed through the upper channel holes. In the process of removing the vertical sacrificial structure, the first stopper layer 219_1 may function as an etch stop layer. By reducing dispersion of protruding lengths of channel holes, a semiconductor device having improved electrical properties and reliability may be manufactured.

Due to the height of the stack structure, sidewalls of the channel structures CH may not be perpendicular to the upper surface of the second substrate 201. The channel structures CH may be formed to be recessed into a portion of the second substrate 201.

The channel dielectric layer 245 may be formed to have a uniform thickness. In this process, the entirety or a portion of the channel dielectric layer 245 may be formed, and a portion extending perpendicularly to the second substrate 201 along the channel structures CH may be formed in this process. The channel layer 240 may be formed on the channel dielectric layer 245 within the channel structures CH. The channel filling insulating layer 247 may be formed to fill the channel structures CH and may be an insulating material. The channel pad 249 may be formed of a conductive material such as, for example, polycrystalline silicon.

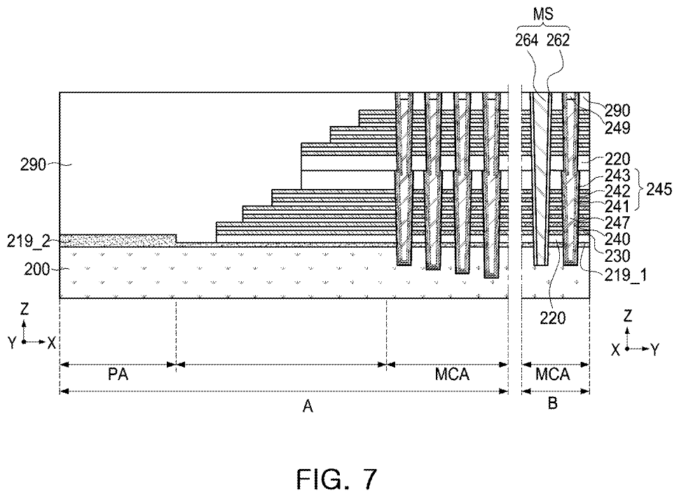

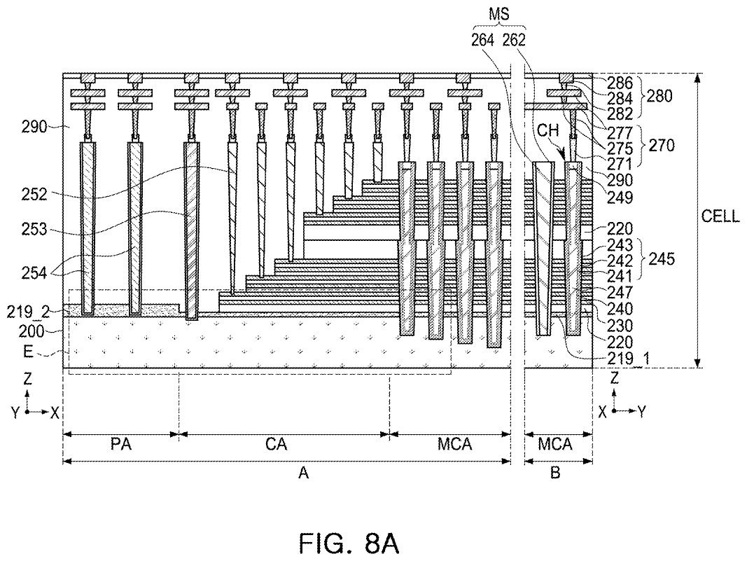

Referring to FIG. 7, gate electrodes 230 may be formed by removing the sacrificial insulating layers (218 in FIG. 6) through the isolation opening (TS in FIG. 6). An isolation region MS may be formed in the isolation opening (TS in FIG. 6).

Tunnel portions may be formed by removing the sacrificial insulating layers 218 through the isolation opening (TS in FIG. 6), and gate electrodes 230 may be formed by filling the tunnel portions with a conductive material. The conductive material may include a metal, polycrystalline silicon or metal silicide material. After forming the gate electrodes 230, the conductive material deposited in the isolation opening TS may be removed through an additional process, and an isolation region MS may be formed by filling the insulating material and the conductive material.

Referring to FIGS. 8A and 8B, an upper interconnection structure including gate contact plugs 252, source contact plugs 253, peripheral contact plugs 254, and channel contact plugs 271 270 may be formed, and an upper bonding structure 280 may be formed.

The gate contact plugs 252 may be formed to be connected to the gate electrodes 230 in the connection region CA, and the source contact plugs 253 and peripheral contact plugs 254 may be formed to be connected to the base substrate 200 in the external side region PA. The channel contact plugs 271 may be formed to be connected to the channel structures CH in the memory cell array region MCA. The gate contact plugs 252, the source contact plugs 253, and the peripheral contact plugs 254 may be formed to different depths. The channel contact plugs 271 may be formed by simultaneously forming contact holes using an etch stop layer and filling the contact holes with a conductive material. In some implementations, a portion of the gate contact plugs 252, source contact plugs 253, and peripheral contact plugs 254 may be formed in a different process.

The contact studs 272, 273, and 274 may be formed to be connected to the gate contact plugs 252, the source contact plugs 253, and the peripheral contact plugs 254, respectively. Upper contact plugs 275 may be formed on the contact studs 272, 273, and 274 and may connect the upper interconnection lines 277 to each other vertically.

Thereafter, the upper bonding structure 280 may be formed in a similar manner to forming the lower bonding structure 180. Accordingly, a memory cell region CELL may be formed. During the process of manufacturing the semiconductor device, the memory cell region CELL may further include the base substrate 200.

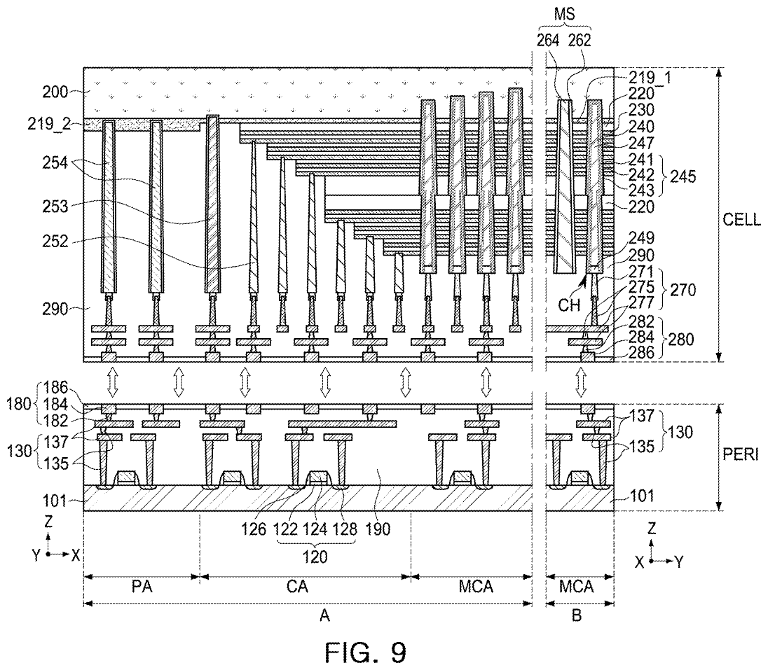

Referring to FIG. 9, a peripheral circuit region PERI that is a first substrate structure and a memory cell region CELL that is a second substrate structure may be bonded to each other.

The peripheral circuit region PERI and the memory cell region CELL may be connected to each other by bonding the lower bonding pad 184 to the upper bonding pad 284 by pressing. The lower bonding insulating layer 186 and the upper bonding insulating layer 286 may be connected by bonding with pressing. The memory cell region CELL on the peripheral circuit region PERI may be turned over and may be bonded such that the upper bonding pad 284 may face downward. The peripheral circuit region PERI and the memory cell region CELL may be directly bonded without using an adhesive such as an adhesive layer.

Referring to FIGS. 10A and 10B, the channel dielectric layer 245 on the base substrate 200 and the channel structure CH may be removed. First, the base substrate 200 may be removed. A portion of the base substrate 200 may be removed from the upper surface by a polishing process such as a grinding process, and the other portion may be removed by an etching process such as wet etching and/or dry etching. In some implementations, the entire base substrate 200 may be removed by an etching process. For example, when the first stopper layer 219_1, the second stopper layer 219_2, the channel dielectric layer 245, and the insulating patterns 235 include an oxide, the etching process may be performed under the condition in which etching is stopped in the oxide. Accordingly, only the base substrate 200 may be selectively removed, such that the source contact plug 253 and the channel structures CH may have a protruding shape in the region from which the base substrate 200 is removed.

Thereafter, the channel dielectric layer 245 on the channel structure CH may be removed. The channel dielectric layer 245 may be removed by a photolithography process and an etching process such as wet etching and/or dry etching. Accordingly, when a subsequent process is performed, the protruding portion 240a of the channel layer may contact the second substrate 201.

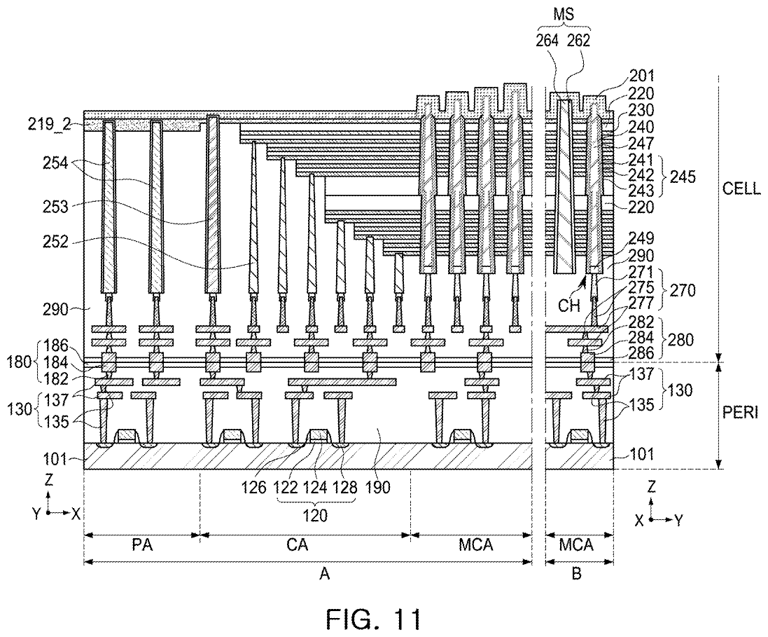

Referring to FIG. 11, a second substrate 201 may be formed.

The second substrate 201 may be formed by depositing N-type doped polysilicon on the first stopper layer 219_1 and the second stopper layer 219_2. The second substrate 201 may be formed to cover the channel structures CH and the isolation region MS. The second substrate 201 may be formed along the protruding channel layer 240, as a non-limiting example. Accordingly, the second substrate 201 and the channel layer 240 may be electrically connected to each other.

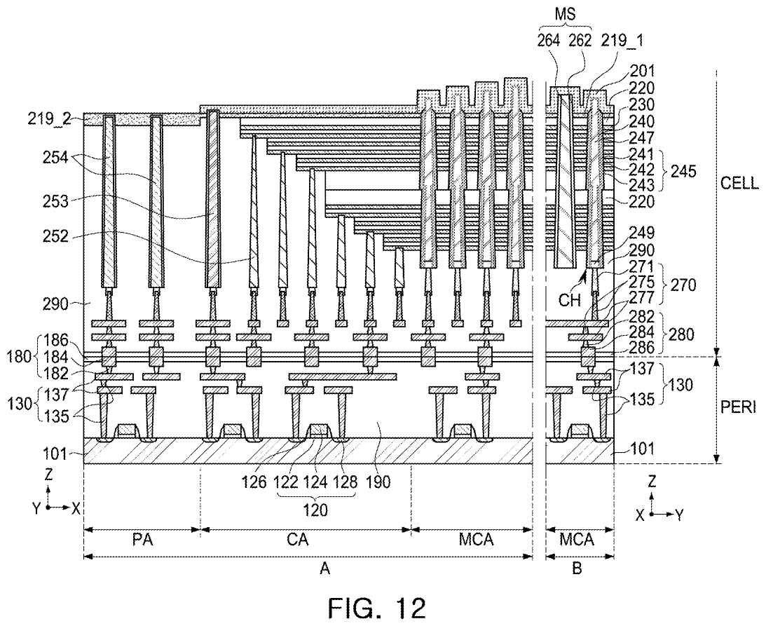

Referring to FIG. 12, the second substrate 201 may be removed from the external side region PA.

The second substrate 201 on the external side region PA may be removed by a photolithography process and an etching process such as wet etching and/or dry etching. For example, the second substrate 201 on the external side region PA may be removed using a mask layer.

Thereafter, referring to FIGS. 2A and 2B together, a portion of an upper insulating layer 295 may be formed, and a peripheral contact via 267 and via patterns 266 may be formed. The peripheral contact via 267 may be formed by forming a via hole penetrating a portion of the upper insulating layer 295 and filling the via hole with a conductive material. The first conductive pad 300 and the second conductive pad 301 may also be formed by partially removing the upper insulating layer 295 and filling the upper insulating layer 295 with a conductive material. Accordingly, the semiconductor device in FIGS. 1 to 2B may be manufactured.

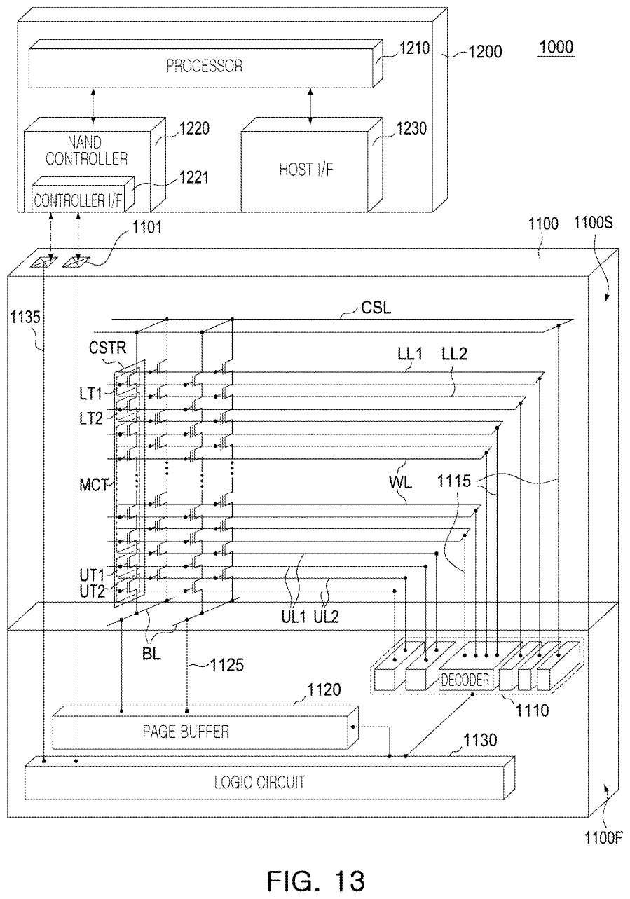

FIG. 13 is a diagram illustrating a data storage system including a semiconductor device according to an example embodiment.

Referring to FIG. 13, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 3B. The semiconductor device 1100 may include a first structure 1100F and a second structure 1100S on the first structure 1100F. In example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bit line BL, a common source line CSL, word lines WL, first and second gate upper lines UL1 and UL2, first and second gate lower lines LL1 and LL2 and memory cell strings CSTR disposed between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in example embodiments.

In example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The word lines WL may be configured as gate electrodes of the memory cell transistors MCT, and the gate upper lines UL1 and UL2 may be configured as gate electrodes of the upper transistors UT1 and UT2, respectively.

In example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistors LT1 and the upper erase control transistor UT2 may be used in an erase operation for erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

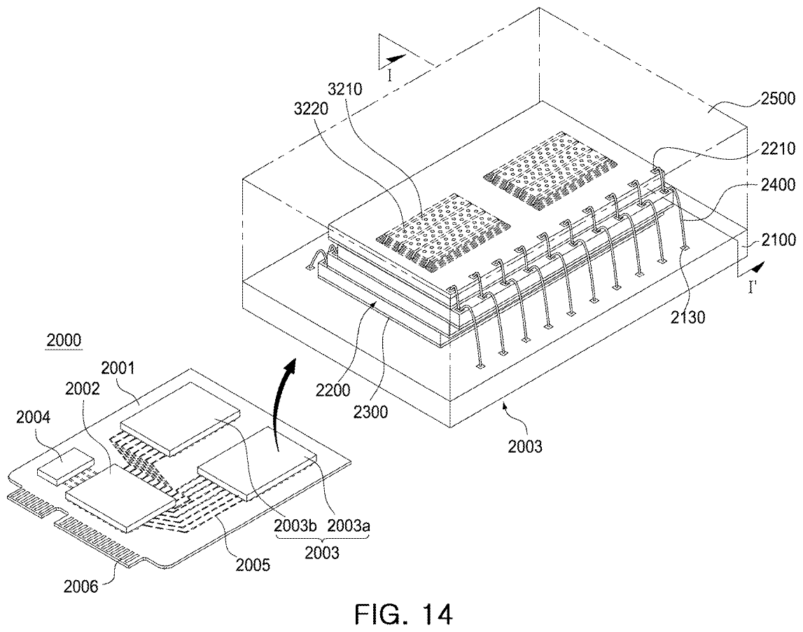

FIG. 14 is a perspective diagram illustrating a data storage system including a semiconductor device according to an example embodiment.

Referring to FIG. 14, a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 13 and may be a region including the first conductive pad 300 in FIG. 2A. Each of the semiconductor chips 2200 may include gate stack structures 3210 and channel structures 3220. Each of the semiconductor chips 2200 may include the semiconductor device described in the aforementioned example embodiment with reference to FIGS. 1 to 3B.

In example embodiments, the connection structure 2400 may be configured as a bonding wire electrically connecting the input/output pad 2210 to the package upper pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In example embodiments, the controller 2002 and the semiconductor chips 2200 may be included in a single package. In an example embodiment, the controller 2002 and the semiconductor chips 2200 may be mounted on a separate interposer substrate different from the main board 2001, and the controller 2002 and the semiconductor chips 2200 may be connected to each other interconnection formed on the interposer substrate.

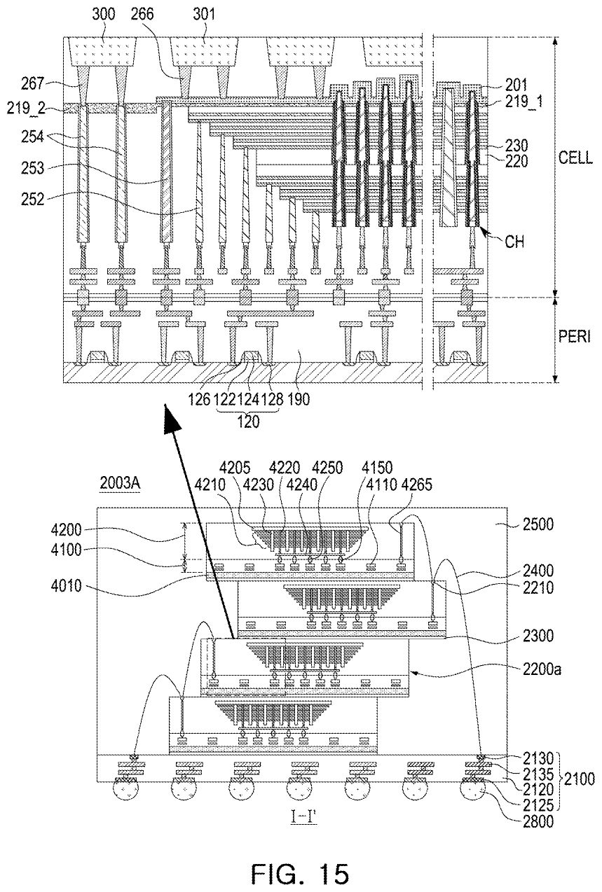

FIG. 15 is a cross-sectional diagram illustrating a semiconductor package in the example embodiment.

FIG. 15 illustrates an example embodiment of the semiconductor package 2003 in FIG. 14 and illustrating a region of the semiconductor package 2003 in FIG. 14 taken along line I-I.

Referring to FIG. 15, in the semiconductor package 2003, the package substrate 2100 may be implemented as a printed circuit board. The package substrate 2100 may include a package substrate body 2120, package upper pads 2130 (see FIG. 14) disposed on the upper surface of the package substrate body 2120, lower pads 2125 disposed on the lower surface of the package substrate body 2120 or exposed through the lower surface, and internal interconnections 2135 electrically connecting the package upper pads 2130 to the lower pads 2125 in the package substrate body 2120. The lower pads 2125 may be connected to the interconnection patterns 2005 of the main substrate 2010 of the data storage system 2000 as illustrated in FIG. 14 through conductive connection portions 2800.

Each of the semiconductor chips 2200 may include a semiconductor substrate 3010 and a first structure 3100 and a second structure 3200 stacked in sequence on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 penetrating through the gate stack structure 3210, bit lines 3240 electrically connected to the memory channel structures 3220, and contact plugs 3235 electrically connected to the word lines WL (see FIG. 13) of the gate stack structure 3210. As described in the aforementioned example embodiment with reference to FIGS. 1 to 2B, in each of the semiconductor chips 2200, the thickness D1 of the first stopper layer 219_1 may be less than the thickness D2 of the second stopper layer 219_2, the uppermost end of the peripheral contact plug 254 may be disposed in the second stopper layer 219_2, and the uppermost end of the channel structures CH may be disposed on a level higher than a level of the upper surface of the first stopper layer 219_1, such that the channel structures CH and the second substrate 201 may be electrically connected to each other.

Each of the semiconductor chips 2200 may include a through interconnection 3245 electrically connected to the peripheral interconnections 3110 of the first semiconductor structure 3100 and extending into the second semiconductor structure 3200. The through interconnection 3245 may be disposed on an external side of the gate stack structure 3210 and may be further disposed to penetrate through the gate stack structure 3210. Each of the semiconductor chips 2200 may further include input/output pads 2210 (see FIG. 14) electrically connected to the peripheral interconnections 3110 of the first semiconductor structure 3100.

According to the aforementioned example embodiments by disposing the first stopper layer on the lower surface of the second substrate and the second stopper layer on the external side region of the second substrate, a semiconductor device having improved electrical properties and reliability and a data storage system including the same may be provided.

According to an example embodiment of the present disclosure, a semiconductor device includes a first semiconductor structure including a first substrate, circuit devices on the first substrate, a lower interconnection structure electrically connected to the circuit devices, and a lower bonding structure connected to the lower interconnection structure; and a second semiconductor structure including a second substrate on the first semiconductor structure, a stopper layer in contact with a lower surface of the second substrate and extending in a first direction parallel the lower surface of the second substrate, gate electrodes stacked and spaced apart from each other in a vertical direction perpendicular to a lower surface of the second substrate, channel structures penetrating through the gate electrodes, extending in the vertical direction, and each including a channel layer, an upper interconnection structure below the gate electrodes and the channel structures, a peripheral contact plug spaced apart from the second substrate, and an upper bonding structure connected to the upper interconnection structure and bonded to the lower bonding structure, wherein the channel structures penetrate at least a portion of the stopper layer, and wherein the peripheral contact plug penetrates at least a portion of the stopper layer.

By way of summation and review, an example embodiment provides a data storage system including a semiconductor device that can be easily manufactured and that has electrical properties and reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a first semiconductor structure including a first substrate, circuit devices on the first substrate, a lower interconnection structure electrically connected to the circuit devices, and a lower bonding structure connected to the lower interconnection structure; and
a second semiconductor structure including a second substrate on the first semiconductor structure, a stopper layer in contact with a lower surface of the second substrate and extending in a first direction parallel to a lower surface of the second substrate, gate electrodes stacked and spaced apart from each other in a vertical direction perpendicular to a lower surface of the second substrate, channel structures penetrating through the gate electrodes, extending in the vertical direction, and each including a channel layer, an upper interconnection structure below the gate electrodes and the channel structures, a peripheral contact plug spaced apart from the second substrate, and an upper bonding structure connected to the upper interconnection structure and bonded to the lower bonding structure, wherein:
the channel structures penetrate at least a first portion of the stopper layer, and
the peripheral contact plug penetrates at least a second portion of the stopper layer.

2. The semiconductor device as claimed in claim 1, wherein an uppermost end of each of the channel structures is disposed on a level higher than a level of an upper surface of the stopper layer.

3. The semiconductor device as claimed in claim 1, wherein an uppermost end of the peripheral contact plug is in the stopper layer.

4. The semiconductor device as claimed in claim 1, wherein, in the stopper layer, a thickness of a region in contact with the channel structures is less than a thickness of a region in contact with the peripheral contact plug.

5. The semiconductor device as claimed in claim 1, wherein the stopper layer includes an insulating material.

6. The semiconductor device as claimed in claim 1, wherein the second substrate includes a doped polysilicon layer.

7. The semiconductor device as claimed in claim 1, further comprising:
a source contact plug extending from a level lower than a level of a lowermost gate electrode most adjacent to the first semiconductor structure among the gate electrodes to at least an internal region of the second substrate and electrically connected to the second substrate,
wherein the source contact plug penetrates the stopper layer.

8. The semiconductor device as claimed in claim 1, wherein an uppermost end of the channel layer is in contact with the second substrate, and each of the channel structures further includes a gate dielectric layer disposed between the gate electrodes and the channel layer.

9. The semiconductor device as claimed in claim 8, wherein the stopper layer is in contact with the gate dielectric layer.

10. The semiconductor device as claimed in claim 8, wherein:
each of the channel layers protrudes into the second substrate, and
in at least a portion of the channel structures, protruding lengths of the channel layers are different.

11. The semiconductor device as claimed in claim 1, wherein the second semiconductor structure includes:
a peripheral contact via in contact with the upper surface of the peripheral contact plug;
a first conductive pad on the peripheral contact via; and
a second conductive pad electrically connected to the second substrate on the second substrate.

12. A semiconductor device, comprising:
a first semiconductor structure including a first substrate, circuit devices on the first substrate, a lower interconnection structure electrically connected to the circuit devices, and a lower bonding structure connected to the lower interconnection structure; and
a second semiconductor structure including a second substrate on the first semiconductor structure, gate electrodes stacked and spaced apart from each other in a vertical direction perpendicular to a lower surface of the second substrate, channel structures penetrating through the gate electrodes, extending in the vertical direction, and each including a channel layer, an upper interconnection structure below the gate electrodes and the channel structures, and an upper bonding structure connected to the upper interconnection structure and bonded to the lower bonding structure, wherein:
the second semiconductor structure further includes a first stopper layer between a lower surface of the second substrate and an uppermost gate electrode most adjacent to the second substrate among the gate electrodes, and a second stopper layer on an external side region of the second substrate, and
the thickness of the first stopper layer is less than the thickness of the second stopper layer.

13. The semiconductor device as claimed in claim 12, wherein a thickness of the second stopper layer is about 50 nm or greater or about 100 nm or less.

14. The semiconductor device as claimed in claim 12, wherein an upper surface of the first stopper layer and an upper surface of the second stopper are coplanar.

15. The semiconductor device as claimed in claim 12, further comprising: a peripheral contact plug in contact with the second stopper layer in the external side region of the second substrate.

16. The semiconductor device as claimed in claim 15, wherein an uppermost end of the peripheral contact plug is in the second stopper layer.

17. The semiconductor device as claimed in claim 15, wherein the channel structures penetrate the first stopper layer.

18. The semiconductor device as claimed in claim 17,
wherein each of the channel structures further includes a channel dielectric layer between the gate electrodes and the channel layer, and
wherein the channel dielectric layer is in contact with the first stopper layer.

19. A data storage system, comprising:
a semiconductor storage device including a first semiconductor structure including a first substrate and circuit devices on the first substrate; a second semiconductor structure including gate electrodes stacked and spaced apart from each other below a second substrate, and channel structures penetrating through the gate electrodes; and an input/output pad electrically connected to the circuit devices; and
a controller electrically connected to the semiconductor storage device through the input/output pad and controlling the semiconductor storage device,
wherein:
the first semiconductor structure further includes:
a lower interconnection structure electrically connected to the circuit devices, a lower bonding structure connected to the lower interconnection structure,
the second semiconductor structure further includes:
an upper bonding structure bonded to the lower bonding structure;
an upper interconnection structure connected to the upper bonding structure;
a first stopper layer between a lower surface of the second substrate and an uppermost gate electrode most adjacent to the second substrate among the gate electrodes;
a second stopper layer in an external side region of the second substrate, and
wherein a thickness of the first stopper layer is less than a thickness of the second stopper layer and an uppermost end of the channel structures is on a level higher than a level of an upper surface of the first stopper layer.

20. The data storage system as claimed in claim 19, wherein the first stopper layer and the second stopper layer include aluminum oxide (Al₂O₃).
